(19) United States
(12) Patent Application Publication
(10) Pub. No.: US 2011/0272821 A1
(43) Pub. Date: Nov. 10, 2011

(54) Wiring Substrate Manufacturing Method and Wiring Substrate

(76) Inventors: Yuichi TAGUCHI, Nagano-shi (JP); Akinori Shiraishi, Nagano-shi (JP)

(21) Appl. No.: 13/098,620

(22) Filed: May 2, 2011

(30) Foreign Application Priority Data
May 10, 2010 (JP) 2010-108199

(51) Int. Cl. H01L 23/48; H01L 21/768

(52) U.S. Cl. 257/774; 438/667; 257/E21.597; 257/E23.011

(57) ABSTRACT

A wiring substrate manufactured by thinning a silicon substrate, which is coated by an insulation film, from a lower surface to an upper surface to form a substrate body. The substrate body is etched using a resist, which includes an opening, as a mask and the insulation film as an etching stopper layer to form a through hole and a cover, which covers an opening of the through hole at the upper surface of the substrate body. In a state in which the cover is formed, a functional element is formed on the upper surface of a further insulation film at the upper side of the substrate body. Then, a through electrode is formed in at least the through hole.

### BACKGROUND OF THE INVENTION

The present invention relates to a wiring substrate manufacturing method and a wiring substrate.

Through electrodes are arranged in substrates for micromachine packages, referred to as micro-electro-mechanical systems (MEMS) using semiconductor microfabrication technology, and substrates using interposers. A through electrode electrically connects wires arranged on two surfaces (e.g., upper surface and lower surface) of a substrate (refer to, for example, Japanese Laid-Open Patent Publication No. 2006-054307).

A process for forming such a through electrode will now be described with reference to FIG. 7. A case in which electrolytic plating is performed to form a through electrode will be described.

First, as shown in FIG. 7(a), a substrate 81 is prepared. Then, as shown in FIG. 7(b), a through hole 81a, which receives a through electrode, is formed in the substrate 81. Subsequently, as shown in FIG. 7(c), the substrate 81 is thermally oxidized to form an insulation film 82 entirely on the substrate 81 and the wall surface defining the through hole 81a.

Next, as shown in FIG. 7(d), an adhesive film 83 is applied to the lower surface of the substrate 81, and a metal foil 84 is adhered by the adhesive film 83 to the lower surface of the substrate 81. As shown in FIG. 7(e), etching is performed to form an opening 83a, which exposes the metal foil 84, in the adhesive film 83 at a portion corresponding to the through hole 81a.

Referring to FIG. 7(f), the structure shown in FIG. 7(e) is immersed in a plating liquid. Electrolytic plating, which uses the metal foil 84 as a power feeding layer, is performed to deposit and grow a plating film 85 in the through hole 81a. This fills the through hole 81a with the plating film 85. Then, as shown in FIG. 7(g), the adhesive film 83 and the metal foil 84 are removed. Afterward, the plating film 85 projecting out of the upper surface of the substrate 81 is ground to form the through electrode 86.

Referring to FIG. 8, when an element 87 (functional element) is formed on the substrate 81, which includes the through electrode 86, by performing a high temperature process (e.g., sputtering film formation performed at a temperature of approximately 250° C. or annealing performed at a temperature of approximately 600° C.), the through electrode 86 is exposed to high temperatures. This expands the volume of the through electrode 86 (refer to broken line). When the temperature returns to normal, the through electrode 86 may become loose and fall out of the through hole 81a.

To cope with such a problem, as shown in FIGS. 9(a) to 9(d), a functional element may be formed on a substrate prior to the formation of the through electrode. For example, as shown in FIG. 9(a), a through hole 91a is first formed in a substrate 91, and an insulation film 92 is formed entirely on the substrate 91 and the wall surface of the through hole 91a. As shown in FIG. 9(b), a metal film 93 is then formed on the upper surface of the substrate 91 by performing, for example, sputtering. As shown in FIG. 9(c), a resist 94 is formed on the metal film 93 to process the metal film 93 into a desired pattern. As shown in FIG. 9(d), the metal film 93 is etched using the resist 94 as a mask to form a functional element 95 of the desired pattern. Afterward, a through electrode is formed in the through hole 91a. Such a manufacturing method forms the through electrode subsequent to the functional element 95, which is formed by performing a high temperature process. Thus, the through electrode is not exposed to high temperatures. However, as shown in FIGS. 9(b) to 9(d), this method leaves parts (residues) of the metal film 93 and the resist 94 on the wall surface of the through hole 91a. Further, when a through electrode is formed in the through hole 91a with such residues left on the wall surface, the adhesion is decreased between the through electrode and the substrate 91 (more specifically, the insulation film 92 formed on the wall surface of the through hole 91a). Thus, the through electrode may become loose and fall out of the through hole 91a.

### SUMMARY OF THE INVENTION

One aspect of the present invention is a method for manufacturing a wiring substrate. The wiring substrate includes a substrate body having a first surface and a second surface differing from the first surface, a through hole extending through the substrate body between the first surface and the second surface, a through electrode formed in the through hole, and an element formed on the first surface of the substrate body. The method includes forming a cover that closes an opening of the through hole at the first surface, forming the element through a high temperature process in a state in which the cover is formed, and forming the through electrode in at least the through hole after forming the element.

A further aspect of the present invention is a wiring substrate provided with a substrate body including a first surface, a second surface differing from the first surface, and a through hole extending through the substrate body between the first surface and the second surface. A first insulation film is formed on the first surface of the substrate body. An element is formed on the first insulation film. An opening is formed in the first insulation film at a location corresponding to the through hole. The opening has a diameter smaller than that of the through hole. A through electrode formed in the through hole and the opening of the first insulation film, wherein the through electrode is insulated from the substrate body.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic cross-sectional view of a semiconductor device according to a first embodiment of the present invention;

FIGS. 2(a) to 2(g) are cross-sectional views illustrating processes for manufacturing the semiconductor device of the first embodiment;

FIGS. 3(a) to 3(f) are cross-sectional views illustrating processes for manufacturing the semiconductor device of the first embodiment;

FIGS. 4(a) to 4(e) are cross-sectional views illustrating processes for manufacturing a semiconductor device according to a second embodiment of the present invention;

FIGS. 5(a) to 5(f) are cross-sectional views illustrating processes for manufacturing the semiconductor device of the second embodiment;

FIGS. 6(a) to 6(e) are cross-sectional views illustrating processes for manufacturing a semiconductor device in a modified example;

FIGS. 7(a) to 7(g) are cross-sectional views illustrating processes for forming a through electrode;

FIG. 8 is a cross-sectional view showing a first prior art example of a semiconductor device;

FIGS. 9(a) to 9(d) are cross-sectional views illustrating processes for manufacturing a second prior art example of a semiconductor device; and

FIGS. 10(a) to 10(c) are cross-sectional views illustrating processes for manufacturing a comparative example of a semiconductor device.

### DETAILED DESCRIPTION OF THE INVENTION

Embodiments of the invention will now be discussed with reference to the accompanying drawings. The drawings schematically show structures and do not express the actual size.

### First Embodiment

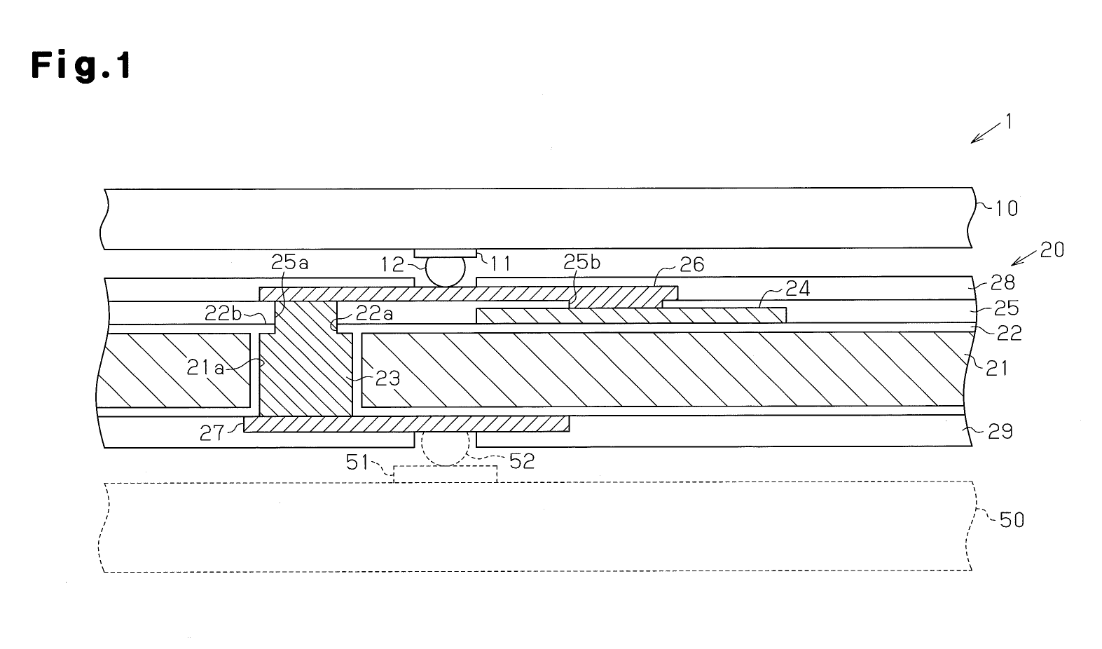

A first embodiment of the invention will now be described with reference to FIGS. 1 to 3.

As shown in FIG. 1, a semiconductor device 1 includes an electronic component 10 and a wiring substrate 20. In the present embodiment, the electronic component 10 is a multilayer wiring structure including a plurality of wires and insulation layers (not shown). The electronic component 10 is, for example, a semiconductor chip.

The wiring substrate 20 includes a substrate body 21, a through electrode 23, and a functional element 24. The through electrode 23 extends through the substrate body 21 from an upper surface (first surface) to a lower surface (second surface) of the substrate body 21. The functional element 24 is electrically connected to the through electrode 23.

The substrate body 21 is a plate-shaped silicon substrate including a through hole 21a, which extends through the substrate body 21 in a thicknesswise direction. An insulation film 22 entirely coats the substrate body 21 and the wall surface (side wall surface) of the through hole 21a. The insulation film 22 may be formed by, for example, a silicon oxide film or a nitride silicon film.

An opening 22a is formed in the insulation film 22 (first insulation film), on the surface (upper surface) of the substrate body 21 that includes the functional element 24, at a location corresponding to the through hole 21a. The opening 22a has a diameter that is smaller than that of the through hole 21a. Thus, the insulation film 22 formed on the upper surface of the substrate body 21 includes an extension 22b that extends over the through hole 21a.

The functional element 24 of a desired pattern is formed on the upper surface of the insulation film 22, which is formed on the upper surface of the substrate body 21. A high temperature process (sputtering and annealing) must be performed to form the functional element 24. The functional element 24 may be a piezoelectric element (lead zirconate titanate (Pb(Zr,Ti)O₃:PZT), a semiconductor device (e.g., transistor and memory), a capacitor, an LED, or the like.

An interlayer insulation film 25 coats the functional element 24 and the upper surface of the insulation film 22, which is formed on the upper surface of the substrate body 21. The interlayer insulation film 25 includes openings 25a and 25b. More specifically, the opening 25a is formed at a location corresponding to the through hole 21a and has a diameter that is smaller than that of the through hole 21a. Further, the opening 25b is formed to expose the functional element 24 at a portion corresponding to a region in which a wire 26 is formed. The interlayer insulation film 25 may be formed from an insulative resin such as epoxy resin or polyimide resin.

The through electrode 23 fills the through hole 21a, which is coated by the insulation film 22, and the openings 22a and 25a. The through electrode 23 includes a top portion, which is substantially flush with the interlayer insulation film 25 at the upper side of the substrate body 21, and a bottom portion, which is substantially flush with the insulation film 22 at the lower side of the substrate body 21. The top portion of the through electrode 23 is connected to part of the wire 26, and the bottom portion of the through electrode 23 is connected to part of a wire 27. Thus, the through electrode 23 electrically connects the wires 26 and 27. The through electrode 23 is formed from, for example, copper (Cu). Further, the wires 26 and 27 are formed from, for example, copper, nickel (Ni), nickel alloy, or the like.

A void defined by the through hole 21a and the opening 22a includes a step formed by the extension 22b and the insulation film 22 on the wall surface of the through hole 21a. When the through electrode 23 is formed in a void including such a step, the through electrode 23 is caught by the lower surface of the extension 22b. This increases the adhesion between the through electrode 23 and the substrate body 21 (more specifically, the insulation film 22 formed on the wall surface of the through hole 21a) and prevents the through electrode 23 from becoming loose and falling out of the through hole 21a.

The wire 26 includes a first end portion, which is connected to the top portion of the through electrode 23, and a second end portion, which is connected to the upper surface of the functional element 24 through the opening 25b. Further, a bump 12, which is arranged on an electrode pad 11 of the electronic component 10, is connected to the wire 26. An interlayer insulation film 28 is formed on an upper surface (upper layer) of the interlayer insulation film 25 to coat the wire 26, excluding a portion at which the wire 26 is connected to the bump 12.

The wire 27 includes a first end portion, which is connected to the bottom portion of the through electrode 23, and a second end portion, which extends in a predetermined direction (rightward direction as viewed in FIG. 1). Further, a pad 51 of a mounting substrate 50 is connected by an external connection terminal 52 to the wire 27. An interlayer insulation film 29 is formed on a lower surface of the insulation film 22 to coat the wire 27, excluding a portion at which the wire 27 is connected to the external connection terminal 52.

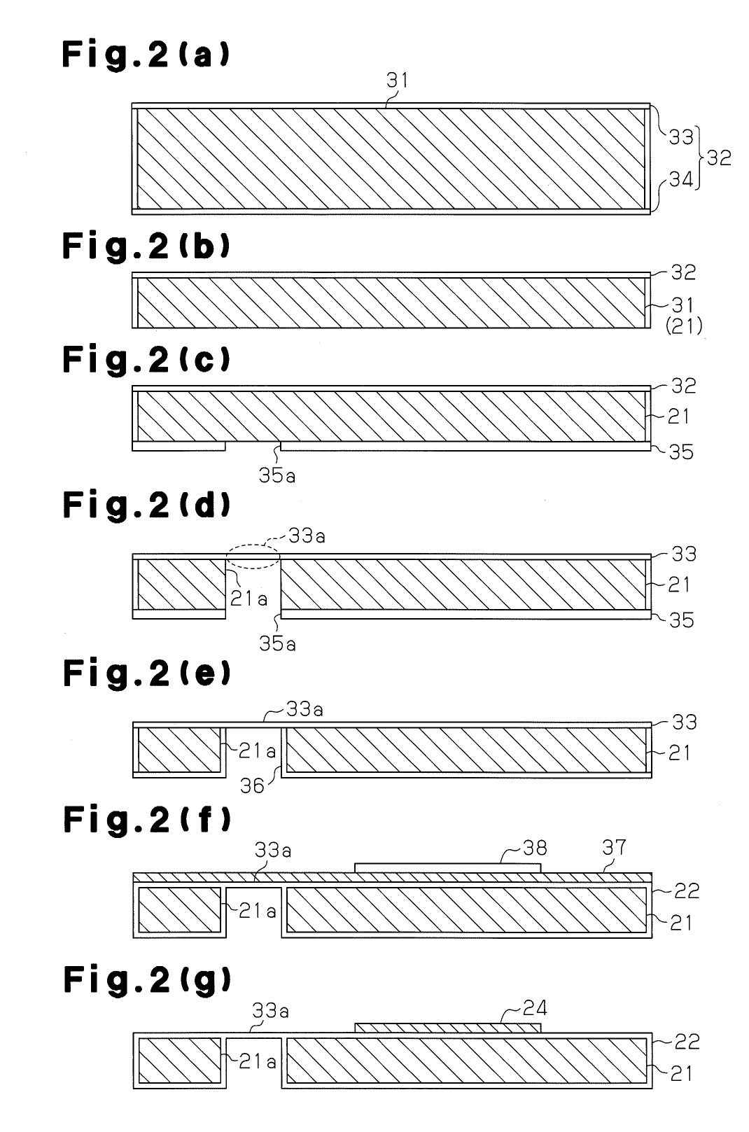

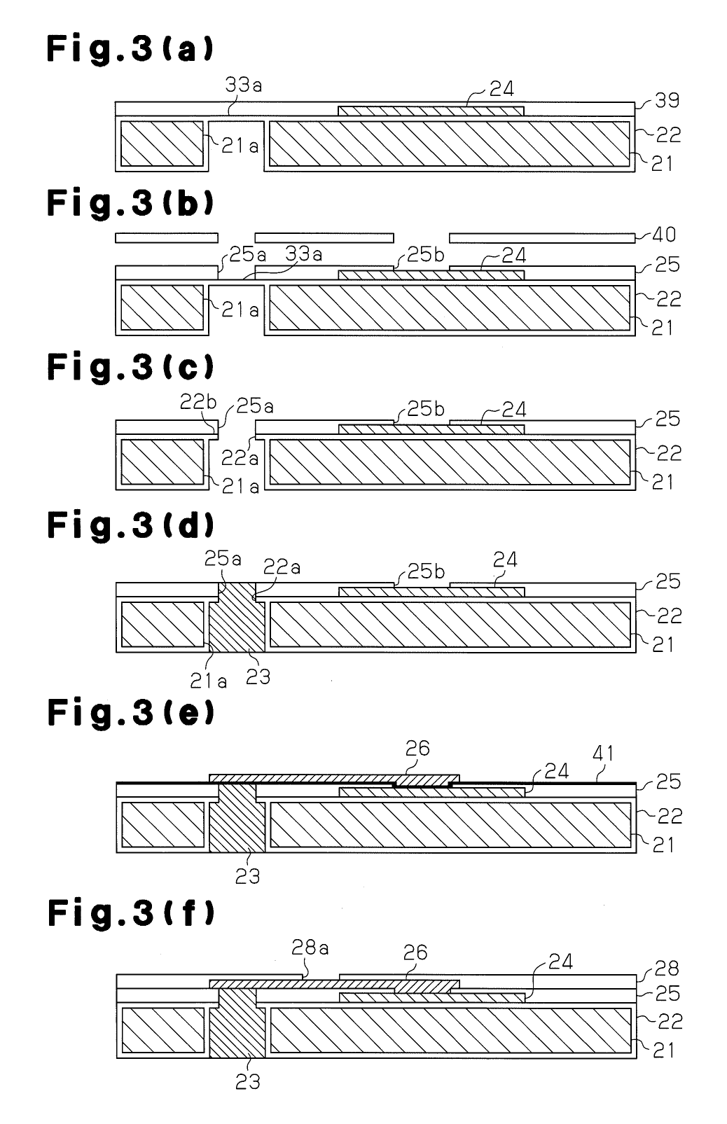

A method for manufacturing the wiring substrate 20 will now be described with reference to FIGS. 2 and 3.

First, as shown in FIG. 2(a), a silicon substrate 31, which is the base material of the substrate body 21, is prepared. The silicon substrate 31 has a thickness of, for example, 725 to 775 μm. The silicon substrate 31 is coated by an insulation film 32, which is a silicon oxide film. The insulation film 32 includes an insulation film 33, which is formed on the upper surface of the silicon substrate 31, and an insulation film 34, which is formed on the lower surface of the silicon substrate 31. The insulation film 32 has a thickness of, for example, 1.0 to 1.5 μm.

Next, as shown in FIG. 2(b), the lower surface of the silicon substrate 31 is ground by performing, for example, back grinding (BG), to thin the silicon substrate 31. This produces the substrate body 21. The substrate body 21 has a thickness of, for example, 200 μm.

Then, as shown in FIG. 2(c), a resist 35 including an opening 35a, which conforms to the shape of the through hole 21a shown in FIG. 1, is formed in the lower surface (ground surface) of the substrate body 21. The opening 35a has a diameter of 50 to 70 μm.

Referring to FIG. 2(d), the resist 35 is used as a mask and the insulation film 33 is used as an etching stopper layer to etch the substrate body 21 through the opening 35a of the resist 35 by performing high aspect ratio etching (e.g., deep reactive ion etching (DRIE)). This forms the through hole 21a, which extends through the substrate body 21 between the upper and lower surfaces of the substrate body 21. The through hole 21a has a diameter of, for example, 50 to 70 μm.

In this state, the insulation film 32, which is a silicon oxide film, serves as the etching stopper. Thus, only the substrate body 21 is etched, and the insulation film 33 corresponding to through hole 21a remains after the etching. Thus, as shown in FIG. 2(d), the opening of the through hole 21a at the upper side of the substrate body 21 is closed by the insulation film 33. In other words, the processes of FIGS. 2(a) to 2(d) form a cover 33a, which is the insulation film 33 covering the opening of the through hole 21a at the upper side of the substrate body 21. After the through hole 21a is formed, the resist 35 is removed by performing ashing or the like.

Referring to FIG. 2(e), the substrate body 21, which includes the through hole 21a, is thermally oxidized to form an insulation film 36, which is a thermal oxidation film, on the lower surface of the substrate body 21 and the wall surface (side surface) of the through hole 21a. The insulation film 22 shown in FIG. 1 includes the insulation film 36 and the insulation film 33.

Then, referring to FIG. 2(f), sputtering is performed to form a metal film 37 (e.g., PZT film) that coats the upper surface of the insulation film 33 at the upper side of the substrate body 21. Next, a resist 38 is formed on the upper surface of the metal film 37 to process the metal film 37 into a desired pattern. Dry etching is performed on the metal film 37 using the resist 38 as a mask to obtain the functional element 24 with the desired pattern as shown in FIG. 2(g). When the functional element 24 is formed from, for example, PZT, subsequent to the dry etching, annealing is performed under a temperature of 600° C. for 30 minutes in an oxygen atmosphere. Then, the resist 38 is removed by performing aching or the like.

In this manner, the formation of the functional element (formation of the metal film 37, formation of the resist 38, etching of the metal film 37, and removal of the resist 38) is performed in a state in which the opening of the through hole 21a at the upper side of the substrate body 21 is covered by the cover 33a. This prevents the metal film 37 and the resist 38 from entering the through hole 21a and solves the problem of residues of the metal film 37 and the resist 38 remaining on the wall surface of the through hole 21a.

Next, as shown in FIG. 3(a), an interlayer insulation film 39 is formed to coat the upper surface of the insulation film 22 at the upper side of the substrate body 21. As shown in FIG. 3(b), the interlayer insulation film 25, which includes the openings 25a and 25b, is formed by exposing and developing the interlayer insulation film 39 through a mask 40. The opening 25a is formed at a location corresponding to the through hole 21a and exposes part of the cover 33a. The opening 25a has a diameter of, for example, 30 to 40 μm. Further, the opening 25b is formed to expose the upper surface of the functional element 24 at a portion corresponding to the region in which the wire 26 is formed.

Then, as shown in FIG. 3(c), dry etching is performed on the cover 33a using the interlayer insulation film 25 as a mask. This forms the opening 22a, which has a smaller diameter than the through hole 21a, in the cover 33a (the insulation film 22 at the upper side of the substrate body 21) to communicate the through hole 21a and the openings 22a and 25a with one another. In this state, the remaining portion of the cover 33a that is left without being etched forms the extension 22b.

In this manner, the diameter of the opening 25a is smaller than that of the through hole 21a. Thus, even when an exposure displacement occurs when forming the opening 25a, etching is prevented at a portion of the insulation film 22 that does not require etching. This prevents the substrate body 21 from being exposed.

Then, referring to FIG. 3(d), the through electrode 23 is formed in the through hole 21a and the openings 22a and 25a by performing electrolytic plating or by filling a paste. For example, when performing electrolytic plating, the through electrode 23 is formed by applying a copper foil to the lower surface of the substrate body 21, filling copper plating in the through hole 21a and the openings 22a and 25a using the copper foil as a plating power feeding layer, and grinding the copper plating that projects from the upper surface of the interlayer insulation film 25.

In this manner, the through electrode 23 is formed after the functional element 24. Thus, the through electrode 23 is not exposed to high temperatures during the high temperature process performed to form the functional element 24. This prevents volume expansion of the through electrode 23, which, in turn, prevents oxidation of the through electrode 23. Further, the through electrode 23 is prevented from becoming loose and falling out of the through hole 21a.

Then, referring to FIG. 3(e), electrolytic plating is performed to form a seed layer 41 that coats the interlayer insulation film 25, the upper surface of the through electrode 23, and the upper surface of the functional element 24. Subsequently, a resist, which includes an opening pattern corresponding to the shape of the wire 26, is formed on the seed layer 41. Electrolytic plating using the seed layer 41 as a power feeding layer is performed to form the wire 26 in the opening pattern. When the wire 26 is formed, the resist and the unnecessary seed layer 41 are removed.

The interlayer insulation film 28 is then formed to coat the interlayer insulation film 25 and the wire 2. Afterward, as shown in FIG. 3(f), an opening 28a is formed to expose the upper surface of the wire 26 at a portion corresponding to a region in which the bump 12 (refer to FIG. 1) is formed. In the same manner, the wire 27 (refer to FIG. 1) and the interlayer insulation film 29 are formed on the lower surface of the insulation film 22 at the lower side of the substrate body 21. This forms the wiring substrate 20 of the present embodiment.

The present embodiment has the advantages described below.

(1) The formation of the functional element 24 (formation of the metal film 37, formation of the resist 38, etching of the metal film 37, and removal of the resist 38) is performed in a state in which the opening of the through hole 21a at the upper side of the substrate body 21 is covered by the cover 33a. This prevents the metal film 37 and the resist 38 from entering the through hole 21a and solves the problem of residues of the metal film 37 and the resist 38 being left on the wall surface of the through hole 21a. Consequently, the through electrode 23 is prevented from becoming loose and falling out of the through hole 21a.

(2) The through electrode 23 is formed after the functional element 24 is formed. Thus, the through electrode 23 is not exposed to high temperatures during the high temperature process performed to form the functional element 24. This prevents volume expansion of the through electrode 23, which, in turn, prevents oxidation of the through electrode 23. Further, the through electrode 23 is prevented from becoming loose and falling out of the through hole 21a.

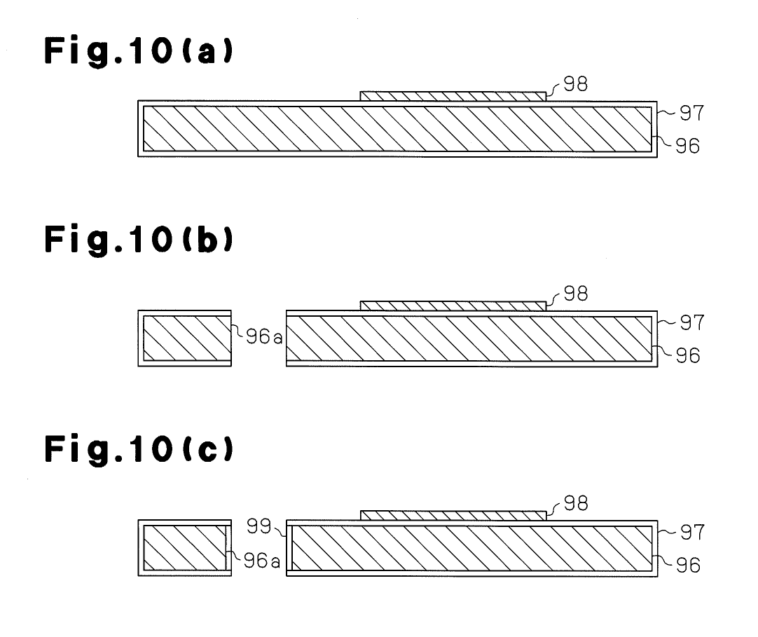

(3) FIGS. 10(a) to 10(c) show an example of how to form the through electrode 23 after the functional element 24 is formed. First, as shown in FIG. 10(a), a functional element 98 is formed on a substrate 96, which is coated by an insulation film 97, before a through electrode is formed. Then, as shown in FIG. 10(b), a through hole 96a, which receives the through electrode, is formed in the substrate 96, which includes the functional element 98. Subsequently, as shown in FIG. 10(c), the substrate 96, which includes the functional element 98, is thermally oxidized to form an insulation film 99 on the wall surface of the through hole 96a. The thermal oxidation is performed under a temperature (approximately 1000° C.) higher than that of the high temperature process for forming the functional element 98. Thus, the functional element 98 is exposed to temperatures higher than the temperature of the high temperature process. This may inflict damages on the functional element 98.

In contrast, the present embodiment forms the functional element 24 after forming the insulation film 36 on the wall surface of the through hole 21a (refer to FIGS. 2(e) to 2(g)). Thus, the functional element 24 is not exposed to temperatures higher than the temperature of the high temperature process. This prevents damages from being inflicted on the functional element 24 in a preferable manner.

(4) The interlayer insulation film 25 is used as a mask when forming the opening 22a of the insulation film 22. This drastically decreases manufacturing steps in comparison to when a mask (e.g., resist) is used just to form the opening 22a.

(5) The through electrode 23 is formed in the through hole 21a and the openings 22a and 25a. This drastically decreases fabrication steps for fabricating the through electrode 23 in the through hole 21a and the openings 22a and 25a in comparison to when forming a via that is separate from the through electrode 23 in the opening 25a after forming the through electrode 23 in the through hole 21a and the opening 22a.

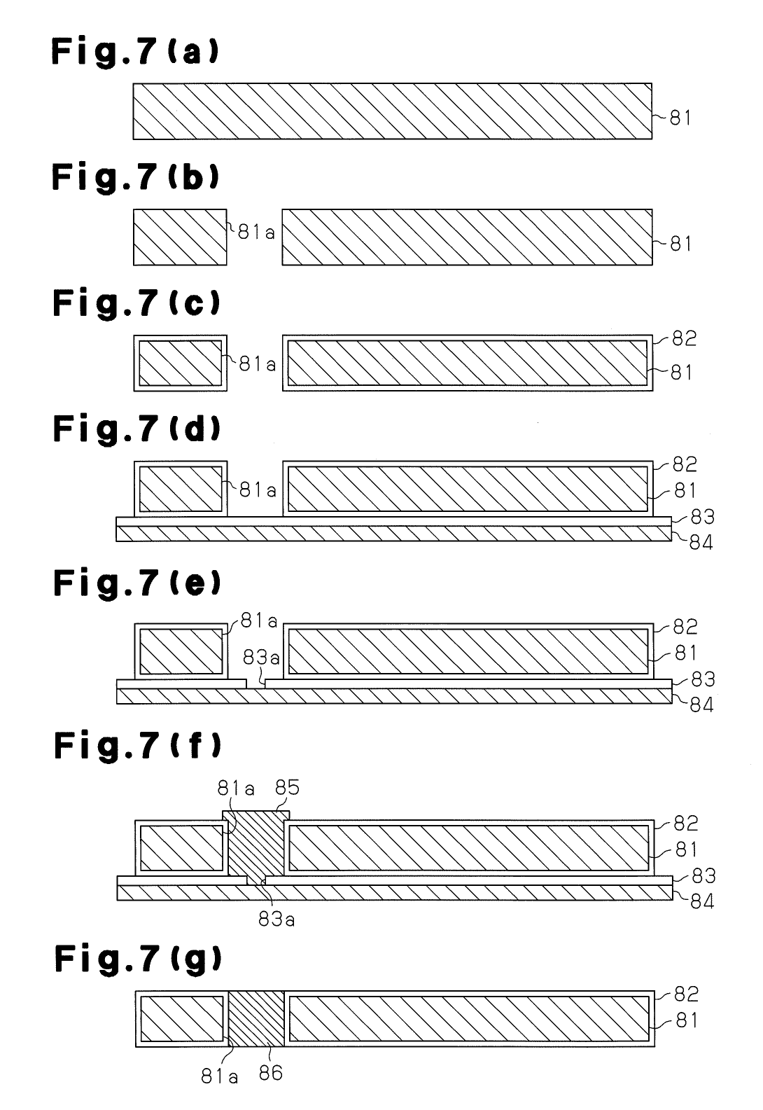

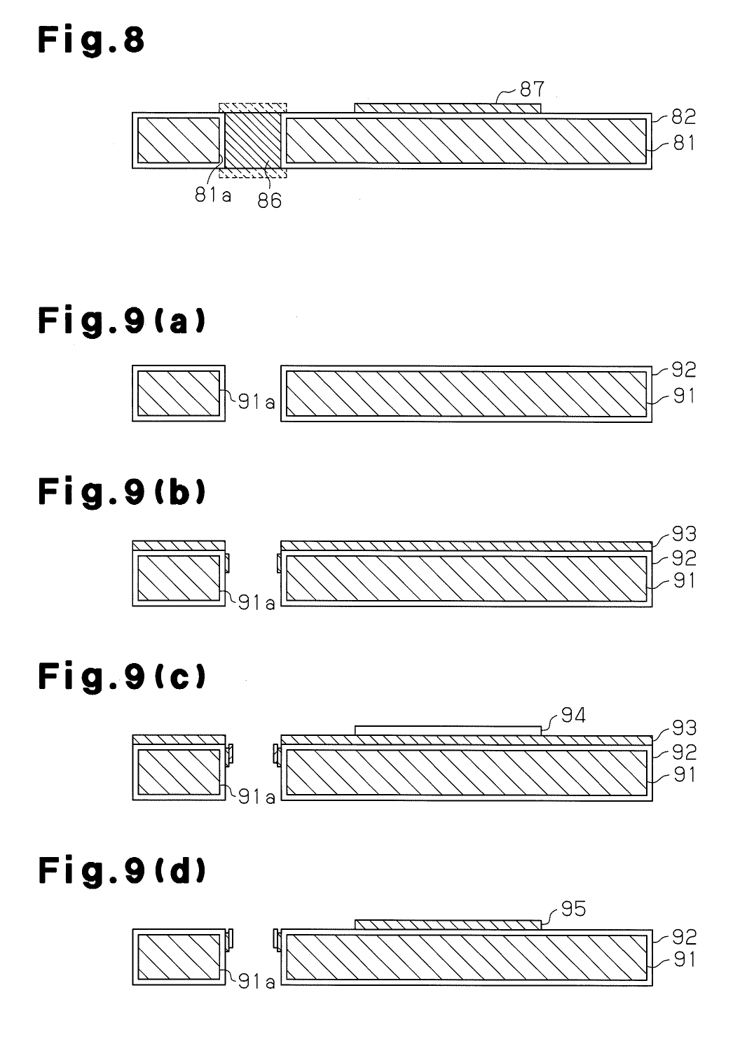

(6) In the manufacturing method of the prior art, regardless of which one of the through electrode 86 and the functional elements 87 and 95 is formed first, the through electrode 86 is fabricated as illustrated in FIGS. 7(a) to 7(g). Thus, the extension 22b of the insulation film 22 of the present embodiment is not formed in the prior art example. Further, the through electrode 86 of the prior art example is formed only in the through hole 81a. This weakens the adhesion between the through electrode 86 and the substrate 81 and loosens the through electrode 86.

In contrast, in the present embodiment, the through electrode 23 is formed in the void defined by the through hole 21a and the opening 22a, the diameter of which is smaller than the through hole 21a. More specifically, the through electrode 23 is formed in the void that includes the step formed by the extension 22b of the insulation film 22 and the insulation film 22 on the wall surface of the through hole 21a. Thus, the through electrode 23 is caught by the lower surface of the extension 22b. This increases the adhesion between the through electrode 23 and the substrate body 21 (more specifically, the insulation film 22 formed on the wall surface of the through hole 21a) and prevents the through electrode 23 from becoming loose and falling out of the through hole 21a.

### Second Embodiment

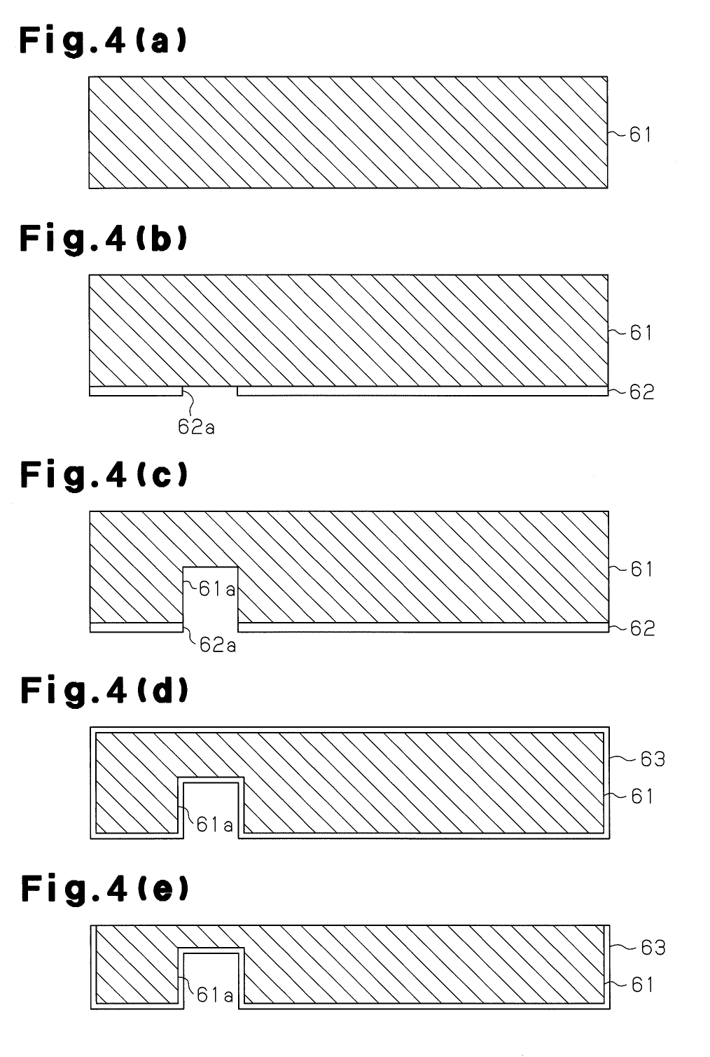

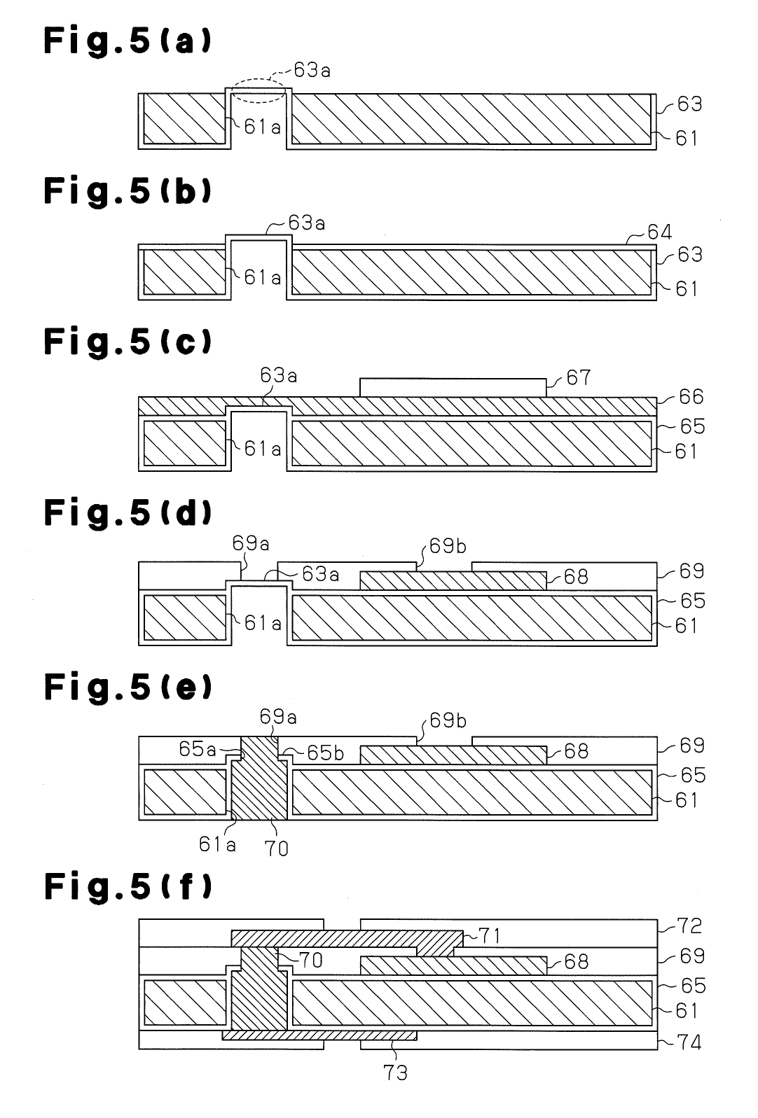

A wiring substrate manufacturing method according to a second embodiment of the present invention will now be discussed with reference to FIGS. 4 and 5.

First, as shown in FIG. 4(a), a silicon substrate 61 is prepared. The silicon substrate 61 has a thickness of, for example, 725 to 775 μm.

Next, as shown in FIG. 4(b), a resist 62 including an opening 62a is formed on the lower surface of the silicon substrate 61. The opening 62a has a diameter of, for example, 50 to 70 μm. Then, as shown in FIG. 4(c), the resist 62 is used as a mask to etch the silicon substrate 61 through the opening 62a of the resist 62 by performing DRIE. This forms a deep hole 61a in the silicon substrate 61. Afterward, asking or the like is performed to remove the resist 62.

Then, as shown in FIG. 4(d), the silicon substrate 61, which includes the deep hole 61a, is thermally oxidized to form an insulation film 63 entirely on the silicon substrate 61 and on a side wall surface and bottom wall surface defining the deep hole 61a. Subsequently, as shown in FIG. 4(e), back grinding is performed to grind the silicon substrate 61 from the upper surface toward the lower surface to thin the silicon substrate 61.

Next, referring to FIG. 5(a), the silicon substrate 61 is etched by performing, for example, wet etching. The wet etching is performed until exposing the insulation film 63 at the bottom surface of the deep hole 61a. The silicon substrate 61 subsequent to the wet etching corresponds to the substrate body 21 shown in FIG. 1, and the deep hole 61a corresponds to the through hole 21a shown in FIG. 1. In this state, an opening of the deep hole 61a, which corresponds to the through hole 21a, at the upper side of the silicon substrate 61 is closed by the insulation film 63. In other words, the processes illustrated in FIGS. 4(a) to 4(e) and 5(a) form a cover 63a, which is defined by the portion of the insulation film 63 covering the opening of the deep hole 61a at the upper side of the silicon substrate 61.

Then, referring to FIG. 5(b), the silicon substrate 61 is thermally oxidized to form an insulation film 64, which is a thermal oxidation film, on the upper surface (ground surface) of the silicon substrate 61. The insulation film 64 and the insulation film 63 correspond to the insulation film 22 shown in FIG. 1. For the sake of brevity, the insulation films 63 and 64 will hereinafter be collectively referred to as an insulation film 65.

Referring to FIG. 5(c), sputtering is performed to form a metal film 66 (e.g., PZT film) that coats the upper surface of the insulation film 65 at the upper side of the silicon substrate 61. Next, a resist 67 is formed on the upper surface of the metal film 66 to process the metal film 66 into a desired pattern. Dry etching is performed on the metal film 66 using the resist 67 as a mask to obtain a functional element 68, which is shown in FIG. 5(d). In this manner, the formation of the functional element 68 (formation of the metal film 66, formation of the resist 67, etching of the metal film 66, and removal of the resist 67) is performed in a state in which the opening of the deep hole 61a at the upper side of the silicon substrate 61 is covered by the cover 63a.

Next, as shown in FIG. 5(d), an interlayer insulation film 69, which includes openings 69a and 69b, is formed to coat the upper surface of the insulation film 65 at the upper side of the silicon substrate 61. The opening 69a is formed at a location corresponding to the deep hole 61a and exposes part of the cover 63a. The opening 69a has a diameter of, for example, 30 to 40 μm.

Referring to FIG. 5(e), dry etching is performed on the cover 63a using the interlayer insulation film 69 as a mask. This forms an opening 65a, which has a smaller diameter than the deep hole 61a, in the cover 33a (the insulation film 65 at the upper side of the silicon substrate 61) to communicate the deep hole 61a and the openings 65a and 69a with one another. In this state, the residue of the cover 63a that is left without being etched forms an extension 65b.

Then, referring to FIG. 5(e), a through electrode 70 is formed in the deep hole 61a and the openings 65a and 69a by performing electrolytic plating or by filling a paste.

A void, receiving the through electrode 70 and defined by the deep hole 61a and the opening 65a, includes a step formed by the extension 65b and the insulation film 65 on the wall surface of the deep hole 61a. When the through electrode 70 is formed in a void including such a step, the through electrode 70 is caught by the lower surface of the extension 65b. This increases the adhesion between the through electrode 70 and the silicon substrate 61 (more specifically, the insulation film 65 formed on the wall surface of the through hole 61a).

Subsequently, in the same manner as the first embodiment, as shown in FIG. 5(f), a wire 71 and an interlayer insulation film 74 are formed on the lower surface of the silicon substrate 61. This forms the wiring substrate of the present embodiment.

The present embodiment has the same advantages as the first embodiment.

It should be apparent to those skilled in the art that the present invention may be embodied in many other specific forms without departing from the spirit or scope of the invention. Particularly, it should be understood that the present invention may be embodied in the following forms.

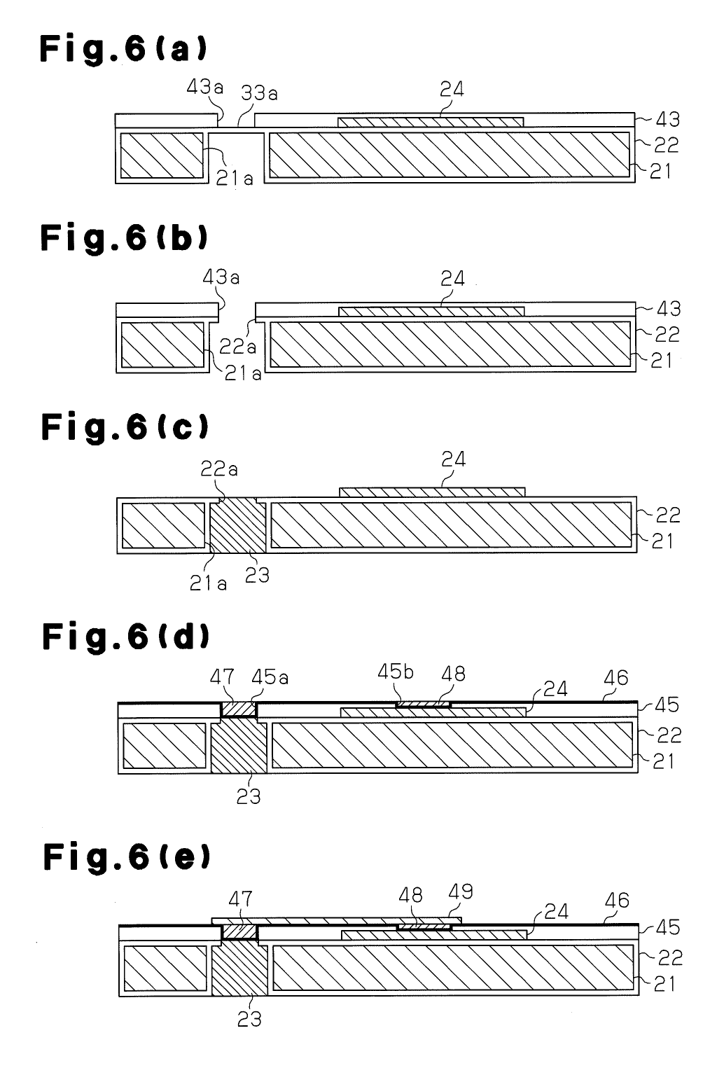

In the embodiments described above, the through electrodes 23 and 70 are formed after the corresponding interlayer insulation films 25 and 69 are formed but not limited in such a manner. For example, as shown in FIGS. 6(a) to 6(e), an interlayer insulation film may be formed after a through electrode is formed. A modification of the manufacturing method of the first embodiment illustrated in FIGS. 3(a) to 3(f) will now be described.

As shown in FIG. 6(a), a resist 43 including an opening 43a is formed on the insulation film 22 at the upper side of the substrate body 21 after the functional element 24 is formed in a state in which the opening of the through hole 21a is covered by the cover 33a. The opening 43a is formed at a location corresponding to the through hole 21a to expose part of the cover 33a. The opening 43a has a diameter of, for example, 30 to 40 μm.

As shown in FIG. 6(b), dry etching is performed on the cover 33a using the resist 43 as a mask. This forms an opening 22a, which has a smaller diameter than the through hole 21a, in the cover 33a (the insulation film 22 at the upper side of the substrate body 21) to communicate the through hole 21a and the opening 22a with each other. Afterward, the resist 43 is removed by performing asking or the like.

Then, referring to FIG. 6(c), the through electrode 23 is formed in the through hole 21a and the opening 22a by performing electrolytic plating or by filling a paste. Next, as shown in FIG. 6(d), after forming an interlayer insulation film 45 that covers the upper surface of the substrate body 21, via holes 45a and 45b are formed in the interlayer insulation film 45. Further, a seed layer 46 is formed to coat the upper surface of the substrate body 21, and via fill plating is performed using the seed layer 46 as a power feeding layer to form vias 47 and 48.

Subsequently, referring to FIG. 6(e), a resist including an opening pattern corresponding to the shape of a wire 49 is formed on the seed layer 46. Further, the wire 49 is formed in the opening pattern by performing electrolytic plating using the seed layer 46 as a power feeding layer. Then, the resist and the unnecessary seed layer 46 are removed. In this case, the interlayer insulation film 45 corresponds to the interlayer insulation film 25 shown in FIG. 1, and the vias 47 and 48 and the wire 49 correspond to the wire 26 shown in FIG. 1.

This manufacturing method also obtains advantages (1) to (3) of the first embodiment.

The etching performed on the covers 33a and 63a in each of the embodiments described above is not particularly limited. For example, etching may be performed on the cover 33a (cover 63a) after forming the functional element 24 (functional element 68) and filling the through hole 21a (deep hole 61a) with resin. In this case, the cover 33a (cover 63a) is etched in a state in which the insulation film 22 (insulation film 65) formed on the wall surface of the through hole 21a (deep hole 61a) is protected.

Further, in the embodiments described above, the covers 33a and 63a are etched to leave parts of the covers 33a and 63a as residues. Instead, the covers 33a and 63a may be etched to completely remove the covers 33a and 63a. In other words, the diameter of the opening 22a may be the same as that of the deep hole 61a.

The present examples and embodiments are to be considered as illustrative and not restrictive, and the invention is not to be limited to the details given herein, but may be modified within the scope and equivalence of the appended claims.

What is claimed is:

1. A method for manufacturing a wiring substrate, wherein the wiring substrate includes a substrate body having a first surface and a second surface differing from the first surface, a through hole extending through the substrate body between the first surface and the second surface, a through electrode formed in the through hole, and an element formed on the first surface of the substrate body, the method comprising:
forming a cover that closes an opening of the through hole at the first surface;
forming the element through a high temperature process in a state in which the cover is formed; and
forming the through electrode in at least the through hole after forming the element.

2. The method according to claim 1, wherein said forming a cover includes:
forming the substrate body by thinning a silicon substrate, which is coated by a first insulation film, from the second surface;
forming a resist on the second surface of the substrate body, wherein the resist includes an opening that is shaped in conformance with the through hole and exposes the substrate body; and
forming the through hole by etching the substrate body using the resist as a mask and the first insulation film as an etching stopper layer.

3. The method according to claim 2, wherein said forming a cover includes forming a second insulation film on a wall surface defining the through hole after forming the through hole.

4. The method according to claim 1, wherein said forming a cover includes:
forming a hole in a silicon substrate, which is a base material of the substrate body, from the second surface;
forming an insulation film entirely on the silicon substrate and on an inner wall surface and bottom wall surface defining the hole;
thinning the silicon substrate from the first surface to the second surface; and
etching the silicon substrate from the first surface to the second surface by performing wet etching until exposing the insulation film formed on the bottom wall surface of the hole to form the substrate body and to form the through hole from the hole.

5. The method according to claim 1, further comprising:
forming an interlayer insulation film on the first surface of the substrate body after forming the element, wherein the interlayer insulation film includes a first opening at a location corresponding to the through hole and the cover; and
forming a second opening corresponding to the first opening in the cover by performing dry etching using the interlayer insulation film as a mask, wherein
said forming the through electrode includes forming the through electrode in the through hole, the first opening, and the second opening, and
a wire connecting the through electrode to an electronic component is formed on the interlayer film.

6. The method according to claim 5, wherein the second opening has a diameter that is smaller than that of the through hole.

7. The method according to claim 5, wherein the second opening has a diameter that is equal to that of the through hole.

8. The method according to claim 1, further comprising:
forming a second resist on the first surface of the substrate body after forming the element, wherein the second resist includes a first opening at a location corresponding to the through hole and the cover;
forming a second opening in the cover by performing dry etching using the second resist as a mask; and
removing the second resist;
wherein said forming the through electrode includes forming the through electrode in the through hole and the second opening.

9. The method according to claim 8, wherein the second opening has a diameter that is smaller than that of the through hole.

10. The method according to claim 8, wherein the second opening has a diameter that is equal to that of the through hole.

11. The method according to claim 1, wherein the cover is a silicon oxide film or a nitride silicon film.

12. A wiring substrate comprising:
a substrate body including a first surface, a second surface differing from the first surface, and a through hole extending through the substrate body between the first surface and the second surface;
a first insulation film formed on the first surface of the substrate body;
an element forming on the first insulation film;
an opening formed in the first insulation film at a location corresponding to the through hole, wherein the opening has a diameter smaller than that of the through hole; and
a through electrode formed in the through hole and the opening of the first insulation film, wherein the through electrode is insulated from the substrate body.
